(19) United States
(12) Patent Application Publication
(10) Pub. No.: US 2014/0074434 A1
(43) Pub. Date: Mar. 13, 2014

(54) METHODS AND APPARATUS FOR END-OF-LIFE ESTIMATION OF SOLID STATE LIGHTING FIXTURES

(71) Applicants: Shane Felix Elias De Lima, Burlington, MA (US); Himanshu Gulabrai Trivedi, Andover, MA (US); Willem Dirk Van Driel, 's-Hertogenbosch (NL)

(72) Inventors: Shane Felix Elias De Lima, Burlington, MA (US); Himanshu Gulabrai Trivedi, Andover, MA (US); Willem Dirk Van Driel, 's-Hertogenbosch (NL)

(73) Assignee: KONINKLIJKE PHILIPS N.V., EINDHOVEN (NL)

(21) Appl. No.: 14/115,398

(22) PCT Filed: May 4, 2012
(86) PCT No.: PCT/IB12/52236

§ 371 Date: Nov. 4, 2013

Related U.S. Application Data
(60) Provisional application No. 61/485,886, filed on May 13, 2011.

(51) Int. Cl. G01R 31/44

(52) U.S. Cl. CPC G01R 31/44
USPC 702/183

(57) ABSTRACT

The present disclosure is directed to methods and apparatus for estimating end-of-life for solid state lighting. By tracking actual operating parameters, such as the temperature (330) and current (320) supplied to a lighting fixture (100) over time and comparing it with estimated life time prediction data (370) stored in a look-up table (360), a precise prediction of the lifetime status of the lighting fixture may be obtained.

### TECHNICAL FIELD

The present invention is directed generally to solid state lighting. More particularly, various inventive methods and apparatus disclosed herein relate to monitoring solid state lighting fixtures to forecast their expected lifetime.

### BACKGROUND

Solid state lighting (“SSL”) technologies, i.e. illumination based on semiconductor light sources, such as light-emitting diodes (LEDs), offer a viable alternative to traditional fluorescent, HID, and incandescent lamps. Functional advantages and benefits of LEDs include high energy conversion and optical efficiency, durability, lower operating costs, and many others. Recent advances in LED technology have provided efficient and robust full-spectrum lighting sources that enable a variety of lighting effects in many applications.

At present, light-emitting diode (LED) lighting systems in various configurations are developed and designed for many purposes, for example, general illumination, advertisement, emergency lighting and urban beautification. LED-based illumination systems have long surpassed the traditional incandescent light sources in efficiency and reliability and have achieved good color rendering. As recent increases in efficiency (approximately 75%), reliability (approximately 50,000 hours) and power density (approx. 100 lm/W) of these systems offer higher lumens per unit cost, SSL is now at the doorstep of massive market entry into offices and homes. Today, many SSL systems are promising lifetimes in the order of 25,000 up to 50.000 hours. Since no installation and/or running test has passed this time yet, an accurate forecast of the lifetime is needed.

Users of lighting fixtures may have different primary concerns regarding the lifespan of the lighting fixture. For example, one user may be primarily concerned being notified when a lighting fixture can no longer provide a minimum adequate level of illumination. Another user may be primarily concerned with the lighting fixture producing a consistent level of illumination throughout the lifespan of the fixture. Yet another user may be primarily concerned with maximizing the lifespan of the fixture, but not as concerned that the illumination level remains constant.

Currently, end-of-life estimations for lighting fixtures have been based largely upon information known at the time of manufacture. However, such estimates do not incorporate information that may more accurately determine the end-of-life of a specific fixture based upon operating conditions, particular to that lighting fixture. Therefore, the end-of-life estimates for current SSL applications may not be adequate based upon several factors in how the SSL lighting fixture is deployed. Such factors may include ambient operating temperatures, ambient humidity levels, the frequency of power cycling, whether the lighting fixture is dimmed during operation, and how much and how often, if so. Further, if the lighting fixture is not left continuously on, it may be difficult for the user to estimate the time of operation for the lighting fixture, thereby making end-of-life estimation more difficult.

End-of-life indicators (sometimes called canaries) are able to forecast the lifetime of a lighting fixture. For example, a direct approach for detecting end-of-life of an SSL is to monitor the output of the SSL using a light detector. Such a detector may indicate when the output of the SSL fell below a threshold level. However, such an approach may be complex and expensive, particularly if such a detector is incorporated directly into the lighting fixture.

Thus, there is a need in the art to provide compact, low cost real time end-of-life estimation for SSL applications based on specific operating conditions of a lighting fixture.

### SUMMARY

The present disclosure is directed to inventive methods and apparatus for estimating lifetimes of solid state lighting fixtures. For example, by tracking the temperature and LED current over time and comparing it with the life time prediction data stored in a look-up table, a reasonably accurate prediction of the expected lifetime of the system may be obtained. The incorporation of actual operating parameters gives this prediction better precision than an initial estimate based on the information known at the time of manufacture and/or the installation, and may be obtained without expensive and complex light sensing devices.

Generally, in one aspect, a method for estimating the end-of-life for a lighting fixture, includes the steps of measuring a time-of-usage for the lighting fixture and providing an end-of-life table having an array of table values indexed by a first index value and a second index value. A step includes periodically measuring a first lighting fixture parameter value and a second lighting fixture parameter value. Another step involves calculating a present average first parameter value from a previous average first parameter value and the first lighting fixture parameter value. Other steps include calculating a present average second parameter value from a previous average second parameter value and the second lighting fixture parameter value, and obtaining an end-of-life value from the end-of-life table using the present average first parameter value as the first table index and the present average second parameter value as the second table index.

In one embodiment of the first aspect, the lighting fixture includes an LED-based lighting unit. Additionally, the first parameter may include a current level, the second parameter may include a temperature, and the table value may be an estimated end-of-life time.

In a second embodiment of the first aspect, the lighting fixture may include an LED-based lighting unit where the first parameter includes a time-of-usage value, the second parameter includes a temperature, and the table value may be a current level.

In a third embodiment, method of the first aspect further includes the steps of comparing the end-of-life value to the time-of-usage value, and if the time-of-usage value exceeds the end-of-life value, activating an end-of-life indicator.

Generally, in a second aspect, a method for controlling a solid state lighting fixture having a driver and a lighting unit includes the steps of measuring a time-of-usage value and providing an end-of-life table. The end of life table includes an array of values estimating an end-of-life time for the lighting fixture indexed by a first index value and a second index value. Other steps include measuring a level of current provided to the lighting unit by the driver, calculating an average current level, measuring a temperature of the lighting unit, and calculating an average operating temperature value. Further steps include obtaining an end-of-life value from a look-up table, where the average current level comprises the first index value and the average operating temperature value comprises the second index value.

In one embodiment of the second aspect, the method includes the steps of comparing the end-of-life value to the time-of-usage value and if the end-of-life value exceeds the time-of-usage value, indicating that the solid state lighting fixture has reached an estimated end-of-life.

In a second embodiment of the second aspect, the method includes the step of adjusting the level of current provided to the lighting unit by the driver to a target current level based at least in part on the end-of-life value. In a third embodiment of the second aspect, the method includes the step of adjusting the level of current provided to the lighting unit by the driver to the target current level based at least in part on the temperature of the lighting unit.

In a fourth embodiment of the second aspect, the method includes the step of adjusting the level of current provided to the lighting unit by the driver to the target current level based at least in part on a constant light output value. In a fifth embodiment of the second aspect, the method includes the step of adjusting the level of current provided to the lighting unit by the driver to the target current level based at least in part on a target minimum lifespan.

Generally, in a third aspect, a lighting fixture apparatus includes an LED-based lighting unit with at least one LED and a temperature sensor and a driver. The driver includes a sensing circuit in electrical communication with the LED-based lighting unit, where the sensing circuit is configured to monitor the temperature sensor and to measure an electric current to the LED-based lighting unit. The driver further includes a controller in electrical communication with the LED-based lighting unit and the sensing circuit. The controller is configured to maintain a time-of-usage value, to read the temperature sensor and the electric current to the LED-based lighting unit, and to regulate the electric current to the LED-based lighting unit. The controller further includes a processor configured to calculate an average electric current and an average temperature, and memory configured to store the average electric current, the average temperature, the time-of-usage value, and an end-of life table. The end-of-life table includes an array of values estimating an end-of-life time for the lighting fixture.

Generally, in a fourth aspect, a system for estimating an end-of-life value for a lighting fixture includes an LED-based lighting unit. The LED-based lighting unit further includes at least one LED and a temperature sensor, and a driver. The driver includes a sensing circuit in electrical communication with the LED-based lighting unit, where the sensing circuit is configured to read a temperature value from the temperature sensor and to measure an electric current value between the driver and the LED-based lighting unit. The driver includes a controller in electrical communication with the LED-based lighting unit and the sensing circuit. The controller is configured to regulate an electric current to the LED-based lighting unit, and to provide access to the temperature value and the electric current value. The driver further includes a processor in communication with the controller. The processor includes memory configured to store an average electric current, an average temperature, and an end-of life table with an array of values estimating an end-of-life time for the lighting fixture. The processor is configured to calculate the average temperature and the average current on a periodic basis, and further configured to retrieve an end-of-life value from the end-of-life table.

Generally, in a fifth aspect, a method for creating a look-up table for a solid state lighting fixture includes the steps of accepting an end-of-life threshold, calculating a lumen output effect, calculating a current effect, calculating a junction temperature effect, generating a look-up table entry indexed by a first index and a second index, and recording the look-up table entry, the first index, and the second index in the look-up table.

As used herein for purposes of the present disclosure, the term “LED” should be understood to include any electroluminescent diode or other type of carrier injection/junction-based system that is capable of generating radiation in response to an electric signal. Thus, the term LED includes, but is not limited to, various semiconductor-based structures that emit light in response to current, light emitting polymers, organic light emitting diodes (OLEDs), electroluminescent strips, and the like. In particular, the term LED refers to light emitting diodes of all types (including semi-conductor and organic light emitting diodes) that may be configured to generate radiation in one or more of the infrared spectrum, ultraviolet spectrum, and various portions of the visible spectrum (generally including radiation wavelengths from approximately 400 nanometers to approximately 700 nanometers). Some examples of LEDs include, but are not limited to, various types of infrared LEDs, ultraviolet LEDs, red LEDs, blue LEDs, green LEDs, yellow LEDs, amber LEDs, orange LEDs, and white LEDs (discussed further below). It also should be appreciated that LEDs may be configured and/or controlled to generate radiation having various bandwidths (e.g., full widths at half maximum, or FWHM) for a given spectrum (e.g., narrow bandwidth, broad bandwidth), and a variety of dominant wavelengths within a given general color categorization.

For example, one implementation of an LED configured to generate essentially white light (e.g., a white LED) may include a number of dies which respectively emit different spectra of electroluminescence that, in combination, mix to form essentially white light. In another implementation, a white light LED may be associated with a phosphor material that converts electroluminescence having a first spectrum to a different second spectrum. In one example of this implementation, electroluminescence having a relatively short wavelength and narrow bandwidth spectrum “pumps” the phosphor material, which in turn radiates longer wavelength radiation having a somewhat broader spectrum.

It should also be understood that the term LED does not limit the physical and/or electrical package type of an LED. For example, as discussed above, an LED may refer to a single light emitting device having multiple dies that are configured to respectively emit different spectra of radiation (e.g., that may or may not be individually controllable). Also, an LED may be associated with a phosphor that is considered as an integral part of the LED (e.g., some types of white LEDs). In general, the term LED may refer to packaged LEDs, non-packaged LEDs, surface mount LEDs, chip-on-board LEDs, T-package mount LEDs, radial package LEDs, power package LEDs, LEDs including some type of encasement and/or optical element (e.g., a diffusing lens), etc.

The term “light source” should be understood to refer to any one or more of a variety of radiation sources, including, but not limited to, LED-based sources (including one or more LEDs as defined above), incandescent sources (e.g., filament lamps, halogen lamps), fluorescent sources, phosphorescent sources, high-intensity discharge sources (e.g., sodium vapor, mercury vapor, and metal halide lamps), lasers, other types of electroluminescent sources, pyro-luminescent sources (e.g., flames), candle-luminescent sources (e.g., gas mantles, carbon arc radiation sources), photo-luminescent sources (e.g., gaseous discharge sources), cathode luminescent sources using electronic satiation, galvano-luminescent sources, crystallo-luminescent sources, kine-luminescent sources, thermo-luminescent sources, triboluminescent sources, sonoluminescent sources, radioluminescent sources, and luminescent polymers.

A given light source may be configured to generate electromagnetic radiation within the visible spectrum, outside the visible spectrum, or a combination of both. Hence, the terms “light” and “radiation” are used interchangeably herein. Additionally, a light source may include as an integral component one or more filters (e.g., color filters), lenses, or other optical components. Also, it should be understood that light sources may be configured for a variety of applications, including, but not limited to, indication, display, and/or illumination. An “illumination source” is a light source that is particularly configured to generate radiation having a sufficient intensity to effectively illuminate an interior or exterior space. In this context, “sufficient intensity” refers to sufficient radiant power in the visible spectrum generated in the space or environment (the unit “lumens” often is employed to represent the total light output from a light source in all directions, in terms of radiant power or “luminous flux”) to provide ambient illumination (i.e., light that may be perceived indirectly and that may be, for example, reflected off of one or more of a variety of intervening surfaces before being perceived in whole or in part).

For purposes of this disclosure, the term “color” is used interchangeably with the term “spectrum.” However, the term “color” generally is used to refer primarily to a property of radiation that is perceivable by an observer (although this usage is not intended to limit the scope of this term). Accordingly, the terms “different colors” implicitly refer to multiple spectra having different wavelength components and/or bandwidths. It also should be appreciated that the term “color” may be used in connection with both white and non-white light.

The term “lighting fixture” is used herein to refer to an implementation or arrangement of one or more lighting units in a particular form factor, assembly, or package. The term “lighting unit” is used herein to refer to an apparatus including one or more light sources of same or different types. A given lighting unit may have any one of a variety of mounting arrangements for the light source(s), enclosure/housing arrangements and shapes, and/or electrical and mechanical connection configurations. Additionally, a given lighting unit optionally may be associated with (e.g., include, be coupled to and/or packaged together with) various other components (e.g., control circuitry) relating to the operation of the light source(s). An “LED-based lighting unit” refers to a lighting unit that includes one or more LED-based light sources as discussed above, alone or in combination with other non LED-based light sources. A “multi-channel” lighting unit refers to an LED-based or non LED-based lighting unit that includes at least two light sources configured to respectively generate different spectrums of radiation, wherein each different source spectrum may be referred to as a “channel” of the multi-channel lighting unit.

The term “controller” is used herein generally to describe various apparatus relating to the operation of one or more light sources. A controller can be implemented in numerous ways (e.g., such as with dedicated hardware) to perform various functions discussed herein. A “processor” is one example of a controller which employs one or more microprocessors that may be programmed using software (e.g., microcode) to perform various functions discussed herein. A controller may be implemented with or without employing a processor, and also may be implemented as a combination of dedicated hardware to perform some functions and a processor (e.g., one or more programmed microprocessors and associated circuitry) to perform other functions. Examples of controller components that may be employed in various embodiments of the present disclosure include, but are not limited to, conventional microprocessors, application specific integrated circuits (ASICs), and field-programmable gate arrays (FPGAs).

In various implementations, a processor or controller may be associated with one or more storage media (generically referred to herein as “memory,” e.g., volatile and non-volatile computer memory such as RAM, PROM, EPROM, and EEPROM, floppy disks, compact disks, optical disks, magnetic tape, etc.). In some implementations, the storage media may be encoded with one or more programs that, when executed on one or more processors and/or controllers, perform at least some of the functions discussed herein. Various storage media may be fixed within a processor or controller or may be transportable, such that the one or more programs stored thereon can be loaded into a processor or controller so as to implement various aspects of the present invention discussed herein. The terms “program” or “computer program” are used herein in a generic sense to refer to any type of computer code (e.g., software or microcode) that can be employed to program one or more processors or controllers.

The term “network” as used herein refers to any interconnection of two or more devices (including controllers or processors) that facilitates the transport of information (e.g. for device control, data storage, data exchange, etc.) between any two or more devices and/or among multiple devices coupled to the network. As should be readily appreciated, various implementations of networks suitable for interconnecting multiple devices may include any of a variety of network topologies and employ any of a variety of communication protocols. Additionally, in various networks according to the present disclosure, any one connection between two devices may represent a dedicated connection between the two systems, or alternatively a non-dedicated connection. In addition to carrying information intended for the two devices, such a non-dedicated connection may carry information not necessarily intended for either of the two devices (e.g., an open network connection). Furthermore, it should be readily appreciated that various networks of devices as discussed herein may employ one or more wireless, wire/cable, and/or fiber optic links to facilitate information transport throughout the network.

The term “user interface” as used herein refers to an interface between a human user or operator and one or more devices that enables communication between the user and the device(s). Examples of user interfaces that may be employed in various implementations of the present disclosure include, but are not limited to, switches, potentiometers, buttons, dials, sliders, a mouse, keyboard, keypad, various types of game controllers (e.g., joysticks), track balls, display screens, various types of graphical user interfaces (GUIs), touch screens, microphones and other types of sensors that may receive some form of human-generated stimulus and generate a signal in response thereto.

The term “time-of-usage” refers to a duration of time when the lighting fixture is in operation, not including time where the lighting fixture is powered off

The term “end-of-life” refers to a time interval after which a lighting fixture is not expected to operate within specified operational tolerances. An example of a threshold used to determine an end-of-life value may include L70, indicating the time after which the lighting fixture is capable of producing at most 70 percent of peak illumination at a maximum current rating. However, different end-of-life thresholds may be used, for instance, L75, L80, or other user selectable threshold values.

The term “constant light output” (CLO) refers to a fixed target level of illumination desired to be maintained over the lifetime of a lighting fixture. Typically, setting a CLO involves reducing the maximum possible light output level at the beginning of a lighting fixture's lifetime by reducing the current level provided to the lighting fixture. Over the course of time, the amount of current provided to the lighting unit may be increased to maintain the fixed target level of illumination.

The term “target minimum lifespan” refers to a length of time a lighting fixture will produce light above an end-of-life illumination threshold. Typically, setting a target minimum lifespan involves reducing the maximum possible light output level at the beginning of a lighting fixture's lifetime in exchange for an expected extension of the life span. However, the actual illumination produced may vary upward or downward depending upon present operating conditions of the lighting fixture.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention.

FIG. 1 illustrates an exemplary embodiment of an LED lighting fixture.

FIG. 2 is a schematic block diagram of an exemplary embodiment of an LED lighting fixture.

FIG. 3 is a flowchart of a first exemplary embodiment of a method to estimate end-of-life for a lighting fixture.

### DETAILED DESCRIPTION

When first deployed, a solid state lighting fixture may provide a maximum illumination level at a rated current, referred to as L100. As described previously, the illumination capacity of solid state lighting fixtures typically degrades over time. Typically, the illumination level will continue to degrade below a suitable level of illumination before a catastrophic failure, for instance, when the lighting fixture fails to provide any illumination. Therefore, the threshold for a minimum level of illumination provided by a lighting fixture may change depending upon the application. This threshold is one example of an end-of-life threshold.

More generally, Applicants have recognized and appreciated that it would be beneficial to provide a method and apparatus enabling a user to define the end-of-life illumination threshold for a lighting fixture, providing an indication when the end-of-life has been reached, and configuring the lighting fixture to provide illumination in accordance with the needs of a given application up until end-of-life and subject to the actual operating conditions and usage history of the lighting fixture.

In view of the foregoing, various embodiments and implementations of the present invention are directed to providing compact, low cost real time end-of-life estimation for SSL applications based on specific operating conditions of a lighting fixture.

### Calculating the End-of-Life

In general, there are three basic end-of-life scenarios for a solid state lighting fixture. Under a first scenario, the user may configure the lighting fixture with a user selected end-of-life illumination level threshold. The end-of-life is reached when the lighting fixture can no longer produce illumination at or above the end-of-life illumination threshold without exceeding a maximum current rating. Under a second scenario, the user may configure a constant threshold level of illumination, for example, L80, and the lighting fixture is configured to provide constant illumination at the threshold level, thereby defining end-of-life as the time when the lighting fixture can no longer provide illumination at the threshold level. Under a third scenario, the user is primarily concerned that the lighting fixture provides illumination for a fixed duration of time. In all three scenarios, the lighting fixture may indicate when end-of-life has been reached. Of course, other end-of-life scenarios are possible within the scope of this disclosure.

Furthermore, as described previously, the end-of-life threshold for a particular lighting fixture may depend upon conditions specific to that lighting fixture, including time-of-usage, temperature, and the provided current level. More precisely, the estimate lifetime of an SSL can be adjusted based on three variable factors. According to fitting rules of the Electrical Illumination Society Technical Memorandum 21 (TM-21), the Lumen Output Effect may be calculated by

$$L 70 = \frac{ln ( \frac{B}{0.7} )}{α} \qquad ( Eq . 1 )$$

where α and B are Weibull parameters. Weibull parameters are statistical numbers that relate the output value, in this case, the failure rate of a lighting fixture, to the input parameters, in this case time, current and temperature. By way of an analogy, consider the linear function

y=a*x+b (Eq. 2).

Here y is output and x is input, while a and b are parameters that relate x and y. Weibull parameters α and B relate the output value of Eq. 1 to the input values in a similar, albeit more complex manner, as a and b relate to input and output values x and y in the linear equation Eq. 2, as is familiar to persons having ordinary skill in the art.

The time-of-usage, or effective ON time in hours, may be calculated using linear superposition by

T_{effective on}=[T_{on,1}+T_{on,2} . . . ]/24hrs (Eq. 3)

where T_{on,1} represents a first continuous span of time when the lighting fixture is on, and T_{on,2} represents a second continuous span of time when the lighting fixture is on.

The effect of LED current I_{LED} on the end-of-life of an LED lighting fixture may be calculated using the LED lumen depreciation model based on Eq. 1 as

$$L 70 ( kHrs ) = \frac{180}{{( {I}_{LED} / 350 )}^{0.7} \cdot {e}^{( 1000 \cdot ( \frac{1}{60 + 273} ) - ( \frac{1}{{T}_{J} + 273} ) )}} \\ L 70 ( kHrs ) = \frac{180}{{( {I}_{LED} / 350 )}^{0.7} \cdot {e}^{( 1000 \cdot ( \frac{1}{60 + 273} ) - ( \frac{1}{{T}_{J} + 273} ) )}} \qquad ( Eq . 4 )$$

where the current effect is controlled by the denominator.

Based on above equations, the junction temperature effect may be linearized by the relation

1+0.0081*DT (Eq. 5),

where DT is temperature difference from a baseline of 125 degrees Celsius. The temperature may be used to approximate the illumination output level of the lighting fixture. It may be advantageous to use temperature to approximate illumination level instead of directly measuring illumination level with a light sensor, since temperature sensors are generally simpler less expensive than light sensors.

A table of estimated end-of-life values may be calculated by applying a range of current values and temperature values to the above equations and recording the resultant end-of-life value as a table entry indexed by, for example, the input current value and input temperature value. The end-of-life table is described further below.

### Lighting Fixture

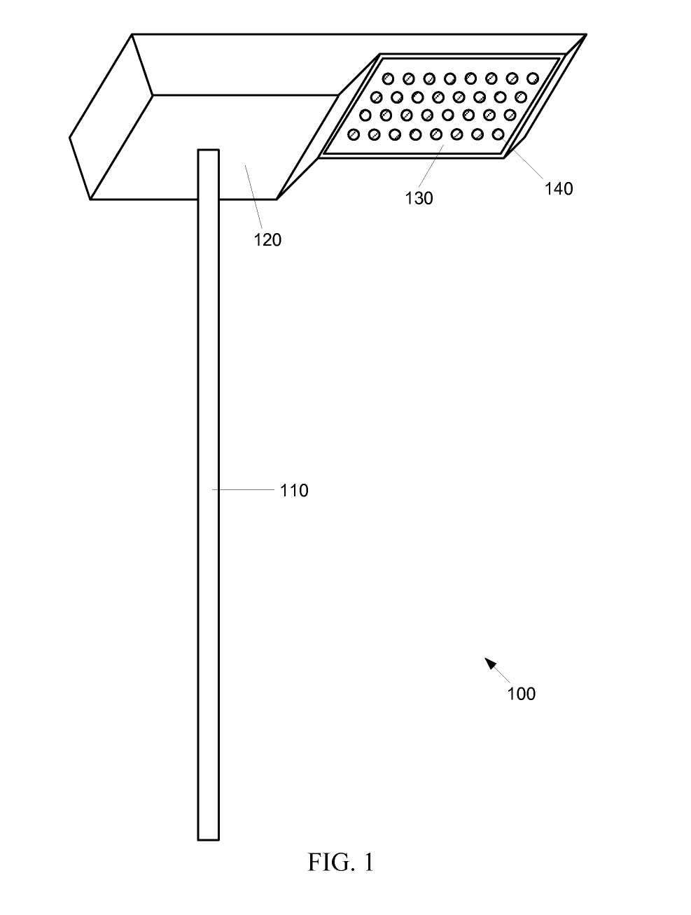

Referring to FIG. 1, in a first embodiment, a lighting fixture 100 is configured for overhead lighting. A support 110 may serve as a stand for the lighting fixture and as a conduit for electrical connections, for example, AC power mains. The support 110 connects to a driver housing 120. The driver housing contains a driver, described below, configured to control, monitor, and regulate power to a connected LED array 130, where the LED array may contain a plurality of LED lighting units 140. It should be noted that other embodiments may have more or fewer LED lighting units than depicted in the first embodiment.

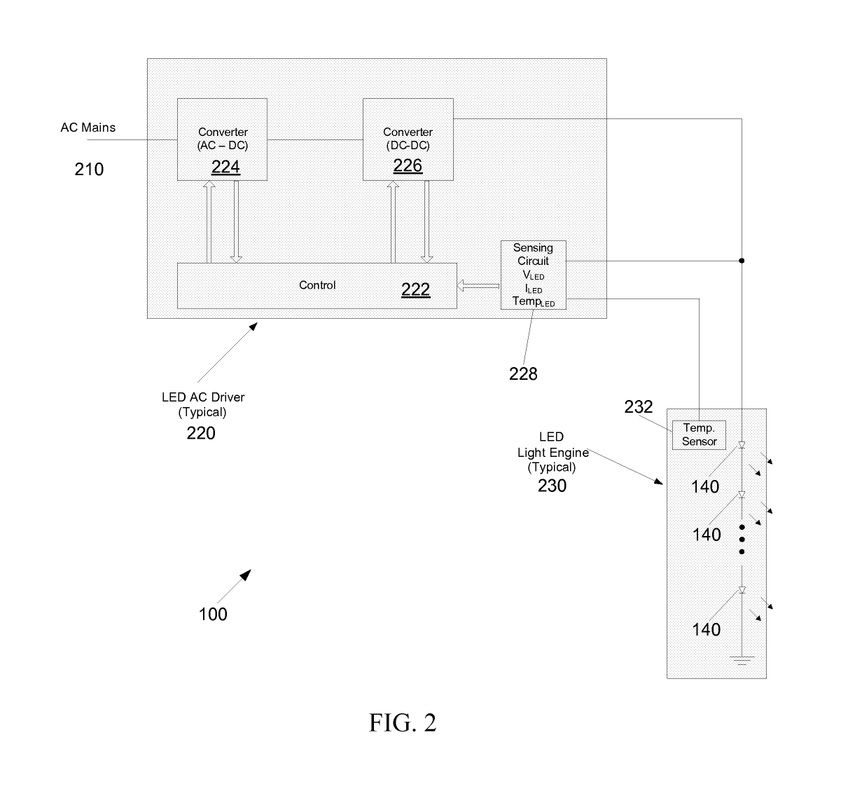

Referring to FIG. 2, a schematic block diagram of a second embodiment of a lighting unit 100 includes two main elements, including an LED AC driver 220 and an LED light engine 230. Power is supplied to the driver 220 by AC mains 210. The AC/DC converter 224 converts the alternating current from the AC Mains 210 to direct current supplied to a DC/DC converter 226. The AC/DC converter 224 and the DC/DC converter 226 may be controlled by the controller 222. For example, the controller 222 may configure the DC/DC converter 226 to convert a first input current to a second input current. The second input current may then be supplied to LED light engine 230. The LED light engine 230 may contain one or more LED lighting units 140 configured as a lighting array 130 (see FIG. 1).

A sensing circuit 228 may monitor several parameters, for example, the voltage V_{LED} supplied by the driver 220 to the LED light engine 230, the current I_{LED} supplied by the driver 220 to the LED light engine 230, and the temperature TEMP_{LED} of the LED light engine 230, where the TEMP_{LED} is detected by a temperature sensor 232 within the LED light engine 230. The temperature sensor 232 may detect the temperature of the overall LED lighting engine 230 or the temperature of one or more representative LED lighting units 140. The sensing circuit 228 is in communication with the controller 222 and the controller 222 may access temperature, current and voltage parameter values via the sensing circuit 228.

The controller 222 may be configured to measure the time-of-usage of the lighting fixture 100, to read the present voltage and current supplied to the LED light engine 230, the present temperature of the LED light array 130 (see FIG. 1). The controller 222 may use these parameters to estimate the end-of-life of the lighting fixture 100, as described below.

Under the second embodiment, the controller 222 and the sensing circuit 228 are each included in the driver 220. However, there is no objection to other embodiments having the equivalent functionality in different configurations. For example, in a first alternative embodiment the sensing circuit 228 may be included in the LED light engine 230, and the controller 222 may be located externally to the lighting fixture 100 and be in remote communication with the other elements through a wired or wireless network connection. For example, under the second end-of-life scenario described previously, the controller 222 may regulate a level of current to the LED light engine 230 sufficient to provide a constant level of illumination. However, since the illumination capacity of the LED light engine 230 diminishes over time, the controller 222 may factor in the present capacity of the LED light engine 230 to determine the appropriate level of current to supply to the LED light engine 230. In addition, the present temperature of the LED light engine 230 may be taken into account to determine the appropriate level of current to supply to the LED light engine 230.

It should be noted the interface for configuring end-of-life parameters is beyond the scope of this document. However, examples of such an interface might include a push-button interface, a USB connector for communication with an external device such as a thumb-drive, a portable computer or tablet computer, or a wired or wireless network interface.

The lighting fixture 100 may indicate the end-of-life of the fixture has been reached in any of several ways. For example, the controller 222 may regulate the current to the LED light engine 230 so as to periodically blink or slowly fade the light output of the LED light engine 230. For example, the indication may start with five slow fades every week, then five slow fades every day, then, when critically low, by continuous blinking. More sophisticated indication means may include notification through a wired or wireless network, for example, by generating an email or instant message, or otherwise communicating with an external device, such as a laptop computer or tablet computer. However, the specific means for indicating the end-of-life of a lighting fixture are beyond the scope of this document.

### End-of-Life Determination Method

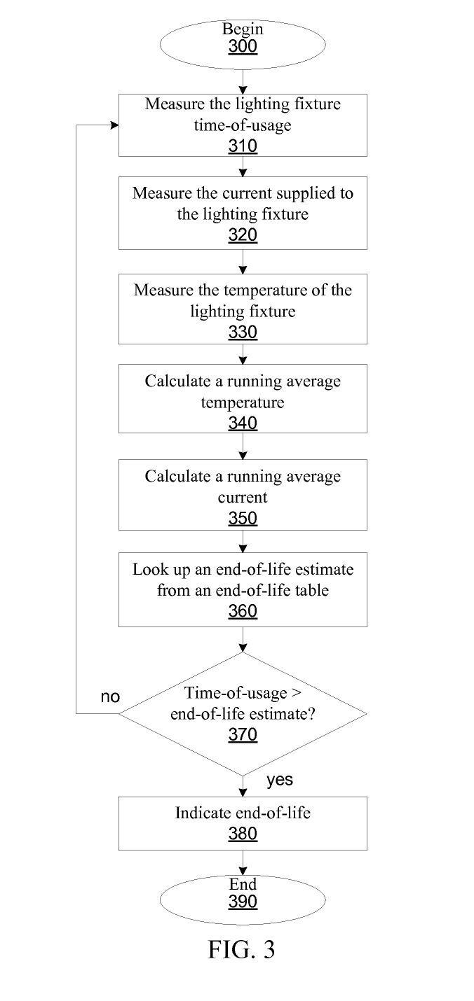

FIG. 3 is a flowchart of a first exemplary embodiment of a method to estimate end-of-life for a lighting fixture. It should be noted that any process descriptions or blocks in flow charts should be understood as representing modules, segments, portions of code, or steps that include one or more instructions for implementing specific logical functions in the process, and alternative implementations are included within the scope of the present invention in which functions may be executed out of order from that shown or discussed, including substantially concurrently or in reverse order, depending on the functionality involved, as would be understood by those reasonably skilled in the art of the present invention.

The method begins at block 300. The time-of-usage for the lighting fixture is calculated as shown by block 310. As described above, the time-of-usage accounts for the amount of time the lighting fixture has been powered on. The current level presently supplied to the lighting fixture is measured (block 320), and the temperature of the lighting fixture is measured (block 330). An average temperature of the lighting fixture (block 340) and an average current level supplied to the lighting fixture (block 350) are calculated. The average current level and the average temperature are used as indexes to look up an end-of-life estimate from an end-of-life table at block 360. The end-of-life table is described further below. It should be noted that if the average temperature and/or average current level do not precisely correspond with index values of the end-of-life table, linear interpolation may be used to calculate the end-of-life value from the nearest adjacent index values.

The time-of-usage value is compared to the end-of-life estimate at block 370. If the time-of-usage exceeds the end-of-life estimate, end-of-life is indicated at block 380. If the time-of-usage does not exceed the end-of-life, the process periodically repeats (blocks 310 to blocks 370). The time interval between the periodic repetitions may be, for example, a week, a day, an hour, etc. The end-of-life value, the average current value and the average temperature value may be stored, for example, in non-volatile memory, for use in subsequent iterations of the method. Additional uses of the stored values are described hereafter.

Note that in other embodiments, the time-of-usage may not exceed the end-of-life estimate before an indication is triggered. For example, end-of-life indication may be configured to occur when the time-of-usage approaches the end-of-life estimate within a given percentage of the end-of-life value, for example, at 95% of the end-of-life value. Alternatively, end-of-life indication may be configured to occur when the time-of-usage is within a fixed amount of time of the end-of-life value, for example, within one month or one week. Similarly, the indicator for near end-of-life may be different from the end-of-life indicator. For example, a near end-of-life indicator may be a periodic of the lighting fixture, where an end-of-life indicator may be a blinking of the lighting fixture. In addition, there may be scenarios where the stored time-of-usage, temperature and current values may be cleared and/or reset. For example, in a lighting fixture 100 (see FIG. 2) where the LED light engine 230 (see FIG. 2) is not physically integrated with the driver 220 (See FIG. 2) the LED light engine (FIG. 2) within the lighting fixture may be replaced independently of the driver 220 (FIG. 2). In this example, the stored values may be reset in accordance with the installation of a new LED light engine 230 (FIG. 2), such that the time-of-usage is reverted to zero, such that subsequent end-of-life measurements are calculated as of the replacement time of the LED light engine 230 (FIG. 2).

### End-of-Life Look-up Table Embodiment

In general, an exemplary embodiment of an end-of-life look-up table, mentioned above, may contain an array of end-of-life values indexed by an average temperature and an average current level. For example, an end-of-life value may be obtained by referencing the end-of-life table with an average current value and an average temperature value, as shown by Table 1

TABLE 1
Exemplary embodiment of an end-of-life look-up table

| | Temperature | | | | |
|---|---|---|---|---|---|
| Current | T₁ | T₂ | • • • | • • • | Tₙ |
| I₁ | t_{1, 1} | t_{1, 2} | • • • | • • • | t_{1, n} |
| I₂ | t_{2, 1} | t_{2, 2} | • • • | • • • | t_{2, n} |
| • | • | • | • | • | • |
| • | • | • | • | • | • |
| • | • | • | • | • | • |
| Iₙ | t_{n, 1} | t_{n, 2} | • • • | • • • | t_{n, n} |

where T is a temperature index, for example, in Kelvin, I is LED a current index, for example, in amperes, and t is an end-of-life value, for example, in hours. Thus, t_{1,1} is the hours until end-of-life at temperature T₁ and current I₁. The end-of-life table may, for example, be programmed into non-volatile memory of an integrated circuit (IC) during production of the lighting fixture, or programmed in the field via a programming interface. The end-of-life table may be customized based on the type of LEDs used, the type of LED system, the nature of the application, etc. As described above, if input current and temperature values do not directly correspond to index values in the end-of-life table, linear interpolation may be used to obtain an end-of-life value from adjacent index values.

In alternative embodiments, the look-up table may be reverse accessed. For example, instead of using a current and a temperature as index values to access an end-of-life value, a time value and a temperature may be used to access a current from the table. An application of such a reverse look-up includes the second scenario, described above, where a constant level of illumination is desired, and end-of-life is defined by a duration after which the lighting fixture is no longer capable of producing the desired level of illumination without exceeding a maximum current rating. In the second scenario, given a table formatted similarly to Table 1, a table column indexed corresponding to the present temperature may be searched to find the present time-of-usage. When the present time-of-usage value is found, the table row corresponding to the found time value yields a current level that may be provided to the lighting fixture by the driver 220 (FIG. 2) to produce the desired level of illumination. It should be noted that instead of reverse accessing a table, an alternative embodiment of a look-up table may be used, wherein the table is indexed by time and temperature to yield a current.

In another embodiment, time and current values may be used to access a temperature value in the look-up table. As described above, a temperature value may be used to estimate an output illumination level for a lighting fixture. As above, the temperature value may be directly obtained with a look-up table indexed by time and current, or indirectly obtained by reverse accessing a look-up table indexed by temperature and current, or with a look-up table indexed by temperature and time.

Look-up tables may be similarly generated for use under the third scenario, where the end-of-life duration is treated as a constant, and the measured time-of-usage and temperature may be used to determine a current level to be applied to the lighting fixture so the end-of-life duration is achieved.

There are other advantages to the embodiments described above, for example, storing a time-of-usage value in the lighting fixture may be helpful in resolving warranty disputes. For instance, if a warranty claim is filed claiming the lighting fixture failed before the warranted time-of-usage, the stored time-of-usage value may be used to verify the actual time-of-usage of the lighting fixture.

While several inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method for estimating the end-of-life for a lighting fixture, comprising the steps of:
measuring a time-of-usage for the lighting fixture;
providing an end-of-life table comprising an array of table values indexed by a first index value and a second index value;
periodically measuring a first lighting fixture parameter value and a second lighting fixture parameter value;
calculating a present average first parameter value from a previous average first parameter value and the first lighting fixture parameter value;
calculating a present average second parameter value from a previous average second parameter value and the second lighting fixture parameter value; and
obtaining an end-of-life value from the end-of-life table using the present average first parameter value as the first table index arid the present average second parameter value as the second table index.

2. The method of claim 1; wherein:
the lighting fixture comprises an LED-based lighting unit;
the first parameter comprises a current level;
the second parameter comprises a temperature; and
the table value comprises an estimated end-of-life time.

3. The method of claim 1; wherein:
the lighting fixture comprises an LED-based lighting unit;
the first parameter comprises a time-of-usage value;
the second parameter comprises a temperature; and
the table value comprises a current level

4. The method of claim 1, further comprising the steps of:
linearly interpolating the end-of-life value based upon the present average first parameter value and the present average second parameter value.

5. The method of claim 1, further comprising the steps of:
comparing the end-of-life value to the time-of-usage value; and
if the time-of-usage value exceeds the end-of-life value, activating an end-of-life indicator.

6. The method of claim 3, further comprising the steps of:
comparing the current value to a maximum rated current value; and
if the current value equals or exceeds the maximum rated current value, activating an end-of-life indicator.

7. The method of claim 1, further comprising the step of accepting an end-of-life threshold value, where the end-of-life threshold value comprises a value representing a diminished illumination capacity of the lighting fixture.

8. A method for controlling a solid state lighting fixture comprising a driver and a lighting unit, the method comprising the steps of:
measuring a time-of-usage value;
providing an end-of-life table comprising an array of values estimating an end-of-life time for the lighting fixture indexed by a first index value and a second index value;
measuring a level of current provided to the lighting unit by the driver;
calculating an average current level;
measuring a temperature of the lighting unit;
calculating an average operating temperature value; and
obtaining an end-of-life value from a look-up table, where the average current level comprises the first index value and the average operating temperature value comprises the second index value.

9. The method of claim 8, further comprising the steps of:
comparing the end-of-life value to the time-of-usage value; and
if the end-of-life value exceeds the time-of-usage value, indicating that the solid state lighting fixture has reached an estimated end-of-life.

10. The method of claim 8, further comprising the step of adjusting the level of current provided to the lighting unit by the driver to a target current level based at least in part on the end-of-life value.

11. The method of claim 10, further comprising the step of adjusting the level of current provided to the lighting unit by the driver to the target current level based at least in part on the temperature of the lighting unit.

12. The method of claim 11, further comprising the step of adjusting the level of current provided to the lighting unit by the driver to the target current level based at least in part on a constant light output value.

13. The method of claim 11, further comprising the step of adjusting the level of current provided to the lighting unit by the driver to the target current level based at least in part on a target minimum lifespan.

14. The method of claim 13, further comprising the step obtaining a target current level from the end-of-life table using the temperature of the lighting unit and the target minimum lifespan.

15. A lighting fixture comprising:
an LED-based lighting unit further comprising at least one LED and a temperature sensor; and
a driver further comprising:
a sensing circuit in electrical communication with the LED-based lighting unit, the sensing circuit configured to monitor the temperature sensor and to measure an electric current to the LED-based lighting unit;
a controller in electrical communication with the LED-based lighting unit and the sensing circuit, the controller configured to maintain a time-of-usage value, to read the temperature sensor arid the electric current to the LED-based lighting unit, and regulate the electric current to the LED-based lighting unit, the controller further comprising:
a processor configured to calculate an average electric current and an average temperature; and
memory configured to store the average electric current, the average temperature, the time-of-usage value, and an end-of life table comprising an array of values estimating an end-of-life time for the lighting fixture.

16. The lighting fixture of claim 15, further comprising:
means to receive input data; and
means to indicate the time-of-usage value has exceeded an end-of-life value.

17. The lighting fixture of claim 16, wherein input data comprises at least one value for the end-of-life table.

18. The lighting fixture of claim 15, wherein input data comprises a consistent light output (CLO) level.

19. The lighting fixture of claim 15, wherein input data comprises a target end-of-life for the LED-based lighting unit.

20. The lighting fixture of claim 19, wherein the processor is configured to calculate a target current level based at least in part upon the constant light output value, arid further configured to communicate the target current level to the controller.

21. A system for estimating an end-of-life value for a lighting fixture comprising:
an LED-based lighting unit further comprising at least one LED and a temperature sensor;
a driver further comprising:
a sensing circuit in electrical communication with the LED-based lighting unit, the sensing circuit configured to read a temperature value from the temperature sensor and to measure an electric current value between the driver and the LED-based lighting unit; and
a controller in electrical communication with the LED-based lighting unit and the sensing circuit, the controller configured to regulate an electric current to the LED-based lighting, and to provide access to the temperature value and the electric current value; and
a processor in communication with the controller further comprising:
memory configured to store an average electric current, an average temperature, and an end-of life table comprising an array of values estimating an end-of-life time for the lighting fixture;
wherein the processor is configured to calculate the average temperature and the average current on a periodic basis, and further configured to retrieve an end-of-life value from the end-of-life table.

22. The system of claim 21, further comprising:
means to receive input data; and
means to indicate an end-of-life value has been reached.

23. The system of claim 22, wherein input data comprises at least one updated value for the end-of-life table and/or a consistent light output (CLO) level,

24. The system of claim 22, wherein input data comprises a target end-of-life for the LED-based lighting unit.

25. The system of claim 24, wherein the processor is configured to calculate a target current level based upon the constant light output value, and further configured to communicate the target current level to the controller.

26. A method for creating a look-up table for a solid state lighting fixture, comprising the steps of:
accepting an end-of-life threshold;
calculating a lumen output effect;
calculating a current effect;
calculating a junction temperature effect;
generating a look-up table entry indexed by a first index and a second index; and
recording the look-up table entry, the first index and the second index in the look-up table,

27. The method of claim 26, wherein the end-of-life threshold comprises a degraded illumination level, the look-up table entry comprises an estimated end-of-life time value, the first index comprises a current value, and the second index comprises a temperature value,

28. The method of claim 26, wherein the end-of-life threshold comprises a constant illumination level, the look-up table entry comprises an estimated end-of-life time value, the first index comprises a current value, and the second index comprises a temperature value.

29. The method of claim 26, wherein the end-of-life threshold comprises a constant illumination level, the look-up table entry comprises current value, the first index comprises a time-in-service value, and the second index comprises a temperature value.

30. The method of claim 26, wherein the end-of-life threshold comprises a target end-of-life time duration value, the look-up table entry comprises current value, the first index comprises a time-in-service value, and the second index comprises a temperature value.
